(19) United States
(12) Patent Application Publication
(10) Pub. No.: US 2007/0165686 A1
(43) Pub. Date: Jul. 19, 2007

(54) Semiconductor laser device, semiconductor laser device mounting structure, semiconductor laser device manufacturing method and semiconductor laser device mounting method

(75) Inventor: Keisuke Miyazaki, Higashihiroshima-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/652,097

(22) Filed: Jan. 11, 2007

(30) Foreign Application Priority Data
Jan. 13, 2006 (JP) 2006-006178

(51) Int. Cl. H01S 5/00; H01S 3/04

(52) U.S. Cl. 372/46.01; 372/43.01

(57) ABSTRACT

An n-type GaAs buffer layer 4, an n-type GaInP intermediate layer 6, an n-type AlGaInP cladding layer 8, a non-doped MQW active layer 10, a p-type AlGaInP cladding layer 12, a p-type AlGaInP cladding layer 14 and a p-type GaAs cap layer 16 are formed on an n-type GaAs substrate 2. The p-type cladding layer 14 and the p-type cap layer 16 are formed in a ridge portion 15, and a narrow width portion 17 is formed including an upper portion of the n-type substrate 2 and the layers there above. An SiO₂ film 18 is formed on the side surfaces of the ridge portion 15, the surfaces of the narrow width portion 17 and the surface of a step portion 2a of the n-type substrate 2. A p-side electrode layer 23 is formed on the surfaces of the SiO₂ film 18 formed on ridge portion 15 and the narrow width portion 17.

### CROSS-REFERENCE TO RELATED APPLICATIONS

This nonprovisional application claims priority under 35 U.S.C. §119(a) on Patent Application No(s). 2006-006178 filed in Japan on Jan. 13, 2006, the entire contents of which are hereby incorporated by reference.

### BACKGROUND OF THE INVENTION

The present invention relates to a semiconductor laser device, a semiconductor laser device mounting structure, a semiconductor laser device manufacturing method and a semiconductor laser device mounting method.

Conventionally, a semiconductor laser device has been used as a light source for read and write of optical disks. FIGS. 8A and 8B are sectional views showing a conventional semiconductor laser device used as a light source for write of DVD (digital versatile disc). The semiconductor laser device is an AlGaInP based red semiconductor laser device of a 200-mW class pulse output. FIG. 8A shows an air ridge type manufactured through one time crystal growth process, and FIG. 8B shows an embedded regrowth type manufactured through two times crystal growth processes. FIGS. 9A and 9B are sectional views showing the semiconductor laser devices 100 and 130 of FIGS. 8A and 8B mounted on respective submounts.

The semiconductor laser device 100 of FIG. 8A has an n-GaAs buffer layer 104, an n-GaInP intermediate layer 106, an n-AlGaInP cladding layer 108, a non-doped MQW (multiple quantum well) active layer 110, a p-AlGaInP cladding layer 112, a p-GaInP etching stop layer 114, a p-AlGaInP cladding layer 116 and a p-GaAs cap layer (including a GaInP intermediate layer) 118 on an n-GaAs substrate 102 and has a ridge portion 128 formed of the p-GaAs cap layer 118 including the GaInP intermediate layer and the p-AlGaInP cladding layer 116 at the center in the widthwise direction. The width and height of the ridge portion 128 are each about 2 μm, and a groove 129 having a width of about 20 μm is formed on both sides in the widthwise direction of the ridge portion 128. A dielectric 120 made of SiO₂ is formed on side surfaces of the ridge portion 128, inner surfaces of the grooves 129 and the surface of the p-GaAs cap layer 118, and optical confinement in the sidewise direction is takes effect inside the ridge portion 128. A p-side electrode 122 is formed on the surface of the dielectric 120 and the surface of the p-GaAs cap layer 118 of the ridge portion 128, and a p-side Au-plated electrode 124 having a thickness of about 3 μm is formed on the p-side electrode 122. Heat generated by laser oscillation is discharged through the p-side Au-plated electrode 124, and a stress distortion when the device is mounted on a submount by brazing is alleviated. An n-side electrode 126 is formed on the lower surface of the n-type GaAs substrate 102. The semiconductor laser device 100 has a width of 180 to 250 μm, a thickness of about 100 μn and a resonator length of about 1000 to 2000 μm.

In the semiconductor laser device 130 of FIG. 8B, a portion under the ridge portion 158 is formed as in the semiconductor laser device 100 of FIG. 8A. That is, an n-GaAs buffer layer 134, an n-GaInP intermediate layer 136, an n-AlGaInP cladding layer 138, a non-doped MQW active layer 140, a p-AlGaInP cladding layer 142 and a p-GaInP etching stop layer 144 are formed on an n-GaAs substrate 132. A ridge portion 158 constructed of a p-AlGaInP cladding layer 145 and a p-GaAs cap layer (including a GaInP intermediate layer) 146 is formed at the center in the widthwise direction on the p-GaInP etching stop layer 144. An n-AlInP block layer 148 and an n-GaAs block layer 149 are formed by regrowth on both sides in the widthwise direction of the ridge portion 158. A p-side electrode 150 is formed on the surface of the n-GaAs block layer 149, and a p-side Au-plated electrode 152 is formed on the p-side electrode 150. Moreover, an n-side electrode 154 is formed on the lower surface of the n-type GaAs substrate 132. The semiconductor laser device 130 has a width of 180 to 250 μm, a thickness of about 100 μm and a resonator length of about 1000 to 2000 μm as in the semiconductor laser device 100 of FIG. 8A.

In the conventional semiconductor laser devices 100 and 130, as shown in FIGS. 9A and 9B, the p-side Au-plated electrodes 124 and 152 are mounted on p-side electrodes 162 and 172 of submounts 160 and 170 via brazing materials 166 and 176. In the thus mounted state, side surfaces of the active layers 110 and 140 of the semiconductor laser devices are exposed to the outside. In FIGS. 9A and 9B, the reference numerals 164 and 174 denote n-side electrodes.

Moreover, conventionally as an AlGaInP based high-power red semiconductor laser device of a 200-mW class output, there is a device that has an n-GaAs buffer layer, an n-AlGaInP cladding layer, an AlGaInP optical guide layer, an InGaP/AlGaInp-MQW active layer, an AlGaInP optical guide layer, a p-AlGaInP cladding layer and a p-InGaP etching stop layer are provided on an n-GaAs substrate and has a ridge portion formed of a p-AlGaInP cladding layer, a p-InGaP intermediate layer and a p-GaAs contact layer on the etching stop layer (refer to JP 2005-093726 A). The semiconductor laser device has a current blocking layer that covers both side surfaces in the widthwise direction of the ridge portion and the surface of the etching stop layer exposed on both sides in the widthwise direction of the ridge portion, and a p-side electrode that covers the surface of the current blocking layer and the upper surface of the contact layer 30. The semiconductor laser device has a width of 200 to 300 μm, a thickness of about 100 to 110 μm and a length of about 1000 to 1500 μm. Moreover, the semiconductor laser device is mounted on a submaount with its p-side electrode connected to an electrode of the submount, and side surfaces of the active layer are exposed to the outside in the mounted state.

However, the conventional semiconductor laser device has a problem of difficulties in dimensional reduction. In detail, if the width of the conventional semiconductor laser device is reduced, the width of the active layer is reduced. Therefore, a contact area of the active layer in contact with other layers is reduced, causing a reduction in heat radiation, and this consequently causes troubles of a shortened operating life and instability in wavelength and the quantity of emitted light. It is noted that the length (depth) in the direction of the resonator length of the semiconductor laser device cannot be reduced because it makes the resonance mode change.

### SUMMARY OF THE INVENTION

An object of the present invention is to provide a semiconductor laser device, which can be reduced in size while preventing a reduction in heat radiation.

In order to achieve the above object, there is provided a semiconductor laser device comprising:

a substrate;

a lower cladding layer formed on the substrate;

an active layer formed on the lower cladding layer;

a first upper cladding layer formed on the active layer;

a dielectric that covers side surfaces of the first upper cladding layer, the active layer and the lower cladding layer; and

an electrode layer that covers the dielectric while being electrically connected to the first upper cladding layer.

According to the construction, carriers are injected into the active layer by a current supplied from the electrode layer, and laser light is generated by an increase in inducted emission. The heat generated in accordance with the emission of the laser light in the active layer is radiated to other layers being in contact with the active layer in the thickness direction. In addition to this, the heat of the active layer is radiated from the side surfaces of the active layer to the outside via the dielectric and the electrode layer. Moreover, the heat that has been radiated in the thickness direction of the active layer and conducted to the first upper cladding layer and the lower cladding layer is radiated to the outside from the side surfaces of the first upper cladding layer and the lower cladding layer via the dielectric and the electrode layer. Therefore, since the heat of the active layer can be radiated with higher efficiency than in the conventional case, the width of the active layer can be reduced while obtaining heat radiation efficiency equivalent to that in the conventional case. As a result, the semiconductor laser device can be reduced in size further than in the conventional case, and the number of devices that can be manufactured from one wafer can be increased further than in the conventional case, allowing the manufacturing cost to be reduced.

It is noted that the width of the active layer means the dimension in the lengthwise direction of the active layer on the emission end surface of the semiconductor laser device.

Moreover, the side surfaces of the first upper cladding layer, the active layer and the lower cladding layer mean the surfaces that are continuous to the emission end surface of the semiconductor laser device and roughly perpendicular to the emission end surface. In other words, the surfaces are parallel to the direction of the resonator length of the semiconductor laser device and roughly perpendicular to the plane in which the layers extend.

In one embodiment of the invention, the electrode layer has a thickness of not smaller than 1 μm and not greater than 50 μm.

According to the embodiment, the heat of the active layer can be effectively radiated to the outside. Furthermore, since the thickness of the electrode layer is not smaller than 1 μm and not greater than 50 μm, a wafer strength can be sufficiently secured, and almost no cost increase is caused even when Au is used for the electrode layer.

In one embodiment of the invention, a ridge portion including a second upper cladding layer and a cap layer is provided between the first upper cladding layer and the electrode layer.

According to the embodiment, a waveguide can be formed of the ridge portion.

In one embodiment of the invention, a narrow width portion having a width smaller than a width of a lower portion of the substrate includes the first upper cladding layer, the active layer and the lower cladding layer and the dielectric covers side surfaces of the narrow width portion.

According to the embodiment, the semiconductor laser device can be reduced in size by effectively reducing the width of the active layer.

In one embodiment of the invention, the narrow width portion includes an upper portion of the substrate.

According to the embodiment, the semiconductor laser device can be reduced in size.

In one embodiment of the invention, the dielectric covers a surface of a step portion continuous to the narrow width portion and covers the surface of the step portion between the upper portion and a lower portion of the substrate.

According to the embodiment, a reliable electrical insulation can be achieved between the substrate and the electrode layer.

In one embodiment of the invention, the electrode layer covers at least part of a portion of the dielectric that covers the surface of the step portion.

According to the embodiment, the semiconductor laser device can be thermally efficiently connected to, for example, a submount by the electrode layer, and the substrate can be effectively insulated with respect to the submount and the electrode layer.

Also, there is provided a semiconductor laser device mounting structure comprising:

the above semiconductor laser device; and

a submount having a recess on an inner surface of which an electrode is formed, wherein

the portion where the electrode layer of the semiconductor laser device is formed is inserted in the recess of the submount, and the electrode layer of the semiconductor laser device and the electrode of the submount are electrically connected together.

According to the construction, the heat generated in the active layer of the semiconductor laser device is efficiently conducted to the submount via the electrode layer of the semiconductor laser device. Therefore, the semiconductor laser device can be reduced in size while securing heat radiation, and the mounting structure of the semiconductor laser device can be reduced in size.

In one embodiment of the invention, the semiconductor laser device mounting structure further comprises:

a brazing material that is provided in the recess and brazes the electrode layer of the semiconductor laser device to the electrode of the submount.

According to the embodiment, the heat generated in the active layer of the semiconductor laser device can be efficiently conducted to the submount via the brazing material.

In one embodiment of the invention, a length of the submount in a direction parallel to a direction of a resonator length of the semiconductor laser device is shorter than the resonator length of the semiconductor laser device.

According to the embodiment, the emission end surface of the semiconductor laser device protrudes from the end surfaces of the submount in the state in which the semiconductor laser device is mounted on the submount. With this arrangement, influences on the emission end surface of the semiconductor laser device due to, for example, the brazing material that connects the semiconductor laser device to the submount can be reduced.

Also, there is provided a semiconductor laser device manufacturing method comprising:

a step for forming a lower cladding layer on a wafer;

a step for forming an active layer on the lower cladding layer;

a step for forming a first upper cladding layer on the active layer;

a groove forming step for forming a groove that reaches at least the lower cladding layer;

a dielectric forming process for forming a dielectric on an inner surface of the groove;

a step for forming an electrode layer, which is electrically connected to the first upper cladding layer, on a surface of the dielectric; and

a step for dividing the wafer, on which the lower cladding layer, the active layer, the first upper cladding layer, the dielectric and the electrode layer are formed, along a bottom surface of the groove.

According to the construction, the lower cladding layer, the active layer and the first upper cladding layer are formed on the wafer, and the groove that reaches at least the lower cladding layer is formed. The dielectric is formed in the groove, and the electrode layer is formed on the surface of the dielectric. The electrode layer is electrically connected to the first upper cladding layer. The wafer on which the lower cladding layer, the active layer, the first upper cladding layer, the dielectric and the electrode layer are formed is divided along the bottom surface of the groove. With this arrangement, the semiconductor laser device in which the electrode layer is formed via the dielectric on the side surfaces of the lower cladding layer, the active layer and the first upper cladding layer is manufactured.

Also, there is provided a semiconductor laser device mounting method comprising:

a step for arranging a brazing material in a recess of a submount wherein an electrode is formed on an inner surface of the recess;

a step for inserting a portion, in which the electrode layer of the semiconductor laser device claimed in claim 1 is formed, into the recess of the submount; and

a step for brazing the electrode layer of the semiconductor laser device to the electrode of the submount by heating the brazing material.

According to the construction, the brazing material is arranged in the recess of the submount, on the inner surface of which the electrode is formed, and the electrode layer of the semiconductor laser device is inserted in the recess. The brazing material is heated, and the electrode layer of the semiconductor laser device is brazed to the electrode of the submount. In the thus-mounted semiconductor laser device, the heat generated in the active layer can be efficiently conducted to the submount via the electrode layer and the brazing material. Therefore, a compact semiconductor laser device can be mounted while securing heat radiation.

As described above, the semiconductor laser device of the present invention has the dielectric that covers the side surfaces of the lower cladding layer, the active layer and the first upper cladding layer formed on the substrate, and the electrode layer that covers the dielectric. Therefore, the heat generated in accordance with the emission of laser light in the active layer can be radiated to the outside from the side surface of the active layer via the dielectric and the electrode layer. Moreover, the heat that has been discharged in the thickness direction of the active layer and conducted to the first upper cladding layer and the lower cladding layer can be discharged to the outside from the side surfaces of the first upper cladding layer and the lower cladding layer via the dielectric and the electrode layer. Therefore, since the heat of the active layer can be radiated with an efficiency higher than in the conventional case, the width of the active layer can be reduced further than in the conventional case while obtaining a heat radiation equivalent to that in the conventional case. As a result, the semiconductor laser device can be reduced in size further than in the conventional case, and the manufacturing cost can be reduced.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a sectional view showing the semiconductor laser device of a first embodiment;

FIGS. 2A through 2D are views showing manufacturing processes of the semiconductor laser device of the first embodiment;

FIGS. 3E to 3H are views showing manufacturing processes of the semiconductor laser device subsequent to FIG. 2D;

FIG. 4 is a view showing manufacturing processes of the semiconductor laser device subsequent to FIG. 3H;

FIG. 5 is a view showing the appearance of the semiconductor laser device mounted on a submount;

FIG. 6 is a sectional view showing the semiconductor laser device of a second embodiment;

FIG. 7 is a sectional view showing the semiconductor laser device of a third embodiment;

FIGS. 8A and 8B are sectional views showing conventional semiconductor laser devices; and

FIGS. 9A and 9B are sectional views showing the appearances of the conventional semiconductor laser devices mounted on respective submounts.

### DETAILED DESCRIPTION OF THE INVENTION

The present invention will be described in detail below by the embodiments shown in the drawings.

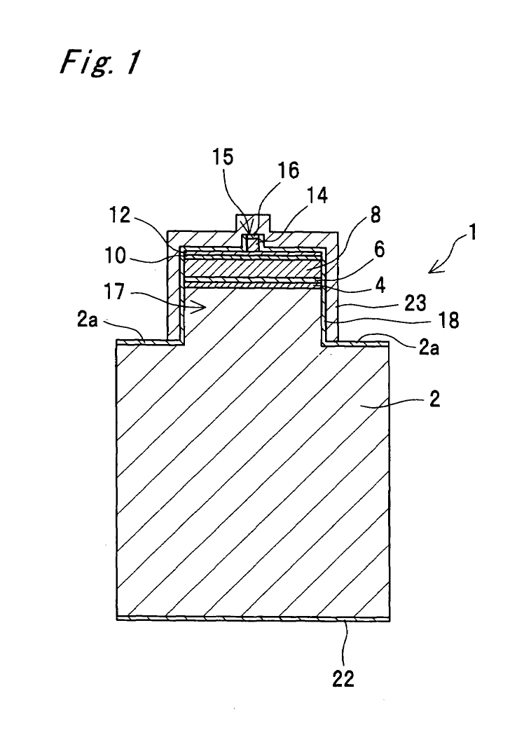

FIG. 1 is a sectional view showing the semiconductor laser device of the first embodiment of the present invention. The semiconductor laser device 1 is a red light-emitting semiconductor laser device that has a 200-mW class pulse output and is formed of an AlGaInP (aluminum gallium indium phosphorus) based semiconductor.

In the semiconductor laser device 1, a 0.25-μm thick n-type GaAs buffer layer 4, a 0.25-μm thick n-type GaInP intermediate layer 6, a 3.0-μm thick n-type AlGaInP cladding layer 8 as a lower cladding layer, a 0.2-μm thick non-doped MQW active layer 10, a 0.25-μm thick p-type AlGaInP cladding layer 12 as a first upper cladding layer, a 1.2-μm thick p-type AlGaInP cladding layer 14 as a second upper cladding layer and a 0.5-μm thick p-type GaAs cap layer 16 are formed on an n-type GaAs (gallium arsenide) substrate 2. Although not shown, the p-type GaAs cap layer 16 includes a 0.035-μm thick p-type GaInP intermediate layer. Moreover, although not shown, a 0.01-μm thick p-type GaInP etching stop layer is formed between the p-type AlGaInP cladding layer 12 and the p-type AlGaInP cladding layer 14. Moreover, although not shown, a 0.035-μm thick non-doped AlGaInP guide layer is formed on the upper surface and the lower surface of the non-doped MQW active layer 10. The non-doped MQW active layer 10 has a multiple quantum well structure in which a 0.005-μm thick non-doped GaInP well layer and a 0.006-μm thick non-doped AlGaInP barrier layer are successively formed.

The layers ranging from an upper portion of the GaAs substrate 2 to the p-type GaInP etching stop layer are formed in a narrow width portion 17 of a width smaller than the width of a lower portion of the GaAs substrate 2. With this arrangement, a step portion 2a is formed between the upper portion and the lower portion of the GaAs substrate 2. Moreover, the p-type AlGaInP cladding layer 14 and the p-type GaAs cap layer 16 are formed in the ridge portion 15 whose width is smaller than the width of the narrow width portion 17.

An SiO₂ (silicon oxide) film 18 as a dielectric is formed on the surface of the step portion of the GaAs substrate 2, the surfaces of the narrow width portion 17 and side surfaces of the ridge portion 15. A p-side electrode layer 23 is formed on the surfaces of the SiO₂ film 18 and the surfaces of the p-type GaAs cap layer 16. The p-side electrode layer 23 is constructed of a Ti (titanium)/Au (gold) layer put in contact with the SiO₂ film 18, an Au-plated layer formed on the surface of the Ti/Au layer and an ohmic electrode formed of AuZn (gold zinc) on the surface of the p-type GaAs cap layer 16. The p-side electrode layer 23 is formed to a thickness of 3 μm and formed excluding a region within a range of 7.5 μm inwardly of both end surfaces in the direction of the resonator length although not shown. It is noted that the p-side electrode layer 23 is advantageous in terms of heat radiation, strength and cost if the thickness thereof is not smaller than 1 μm and not greater than 50 μm. An n-side electrode 22 is formed on the lower surface of the GaAs substrate.

The semiconductor laser device 1 has a width of 40 μm, a height of 60 μm and a resonator length (perpendicular to the sheet plane of FIG. 1) of 1260 μm. The narrow width portion 17 is formed to a width of 25 μm, and the step portion formed on both sides of the narrow width portion 17 is formed to a width of 7.5 μm. The ridge portion 15 is formed to a width of 2.0 μm.

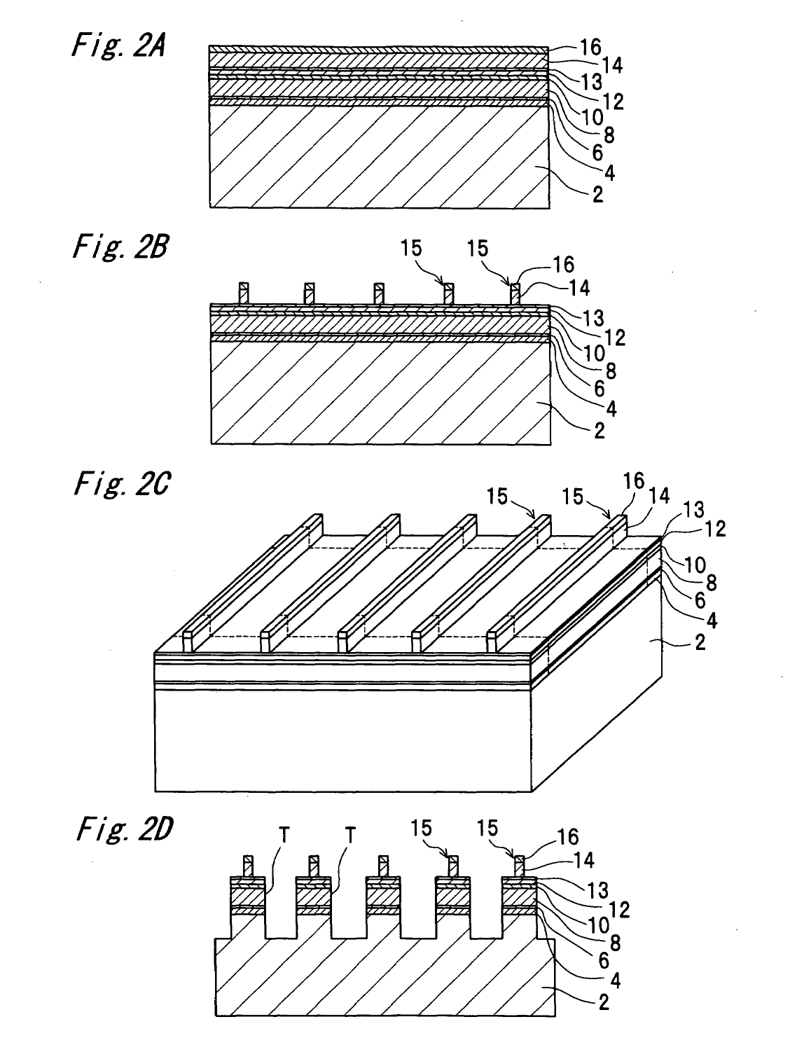

A method for manufacturing the semiconductor laser device 1 is described with reference to FIGS. 2A through 4.

First of all, as shown in FIG. 2A, the n-type GaAs buffer layer 4, the n-type GaInP intermediate layer 6 and the n-type AlGaInP cladding layer 8 are formed on the GaAs substrate 2. It is noted that the GaAs substrate 2 of FIG. 2A is illustrated by picking out part of a GaAs wafer. A non-doped AlGaInP guide layer (not shown) is formed on the n-type AlGaInP cladding layer 8, and the MQW active layer 10 is formed by alternately forming a plurality of non-doped GaInP well layers and a non-doped AlGaInP barrier layer layers on the guide layer, and a non-doped AlGaInP guide layer (not shown) is formed on the MQW active layer 10. The p-type AlGaInP cladding layer 12, the p-type GaInP etching stop layer 13, the p-type AlGaInP cladding layer 14, a p-type GaInP intermediate layer (not shown) and the p-type GaAs cap layer 16 are formed on the non-doped AlGaInP guide layer.

The layers ranging from the n-type GaAs buffer layer 4 to the p-type GaAs cap layer 16 are formed through crystal growth by means of the MOCVD (metal-organic chemical vapor deposition) method.

Subsequently, as shown in FIG. 2B, the portions of the p-type GaAs cap layer 16, the p-type GaInP intermediate layer and the p-type AlGaInP cladding layer 14 are removed by photolithography and etching, forming ridge portions 15 that become a waveguide. The ridge portions 15 are formed mutually separated at intervals of 30 μm.

Next, as shown in FIG. 2C, an emission end surface and an active layer located in a neighborhood portion corresponding to an end surface that opposes to the emission end surface are crystallinically mixed by means of, for example, the Zn (zinc) diffusion method, forming a window structure. The crystallinic mixing process may be carried out before the ridge portions 15 are formed.

Subsequently, as shown in FIG. 2D, grooves T that reach the upper portion of the GaAs substrate 2 are formed leaving portions located within 10 μm from the center of each ridge portion 15 on both sides of the ridge portion 15. The grooves T each have a width of 10 μm and formed mutually separated at intervals of 30 μm. The grooves T are each formed to a depth of 14 μm which is a sum of the thickness of 10 μm of the upper portion of the n-type GaAs substrate 2 and the total thickness of about 4 μm of the p-type GaInP etching stop layer 13, the p-type AlGaInP cladding layer 12, the non-doped AlGaInP guide layer, the non-doped MQW active layer 10, the non-doped AlGaInP guide layer, the n-type AlGaInP cladding layer 8, the n-type GaInP intermediate layer 6 and the n-type GaAs buffer layer 4. The grooves T are formed by means of photolithography and etching with a chemical liquid or dry etching. The grooves T may be formed by dicing.

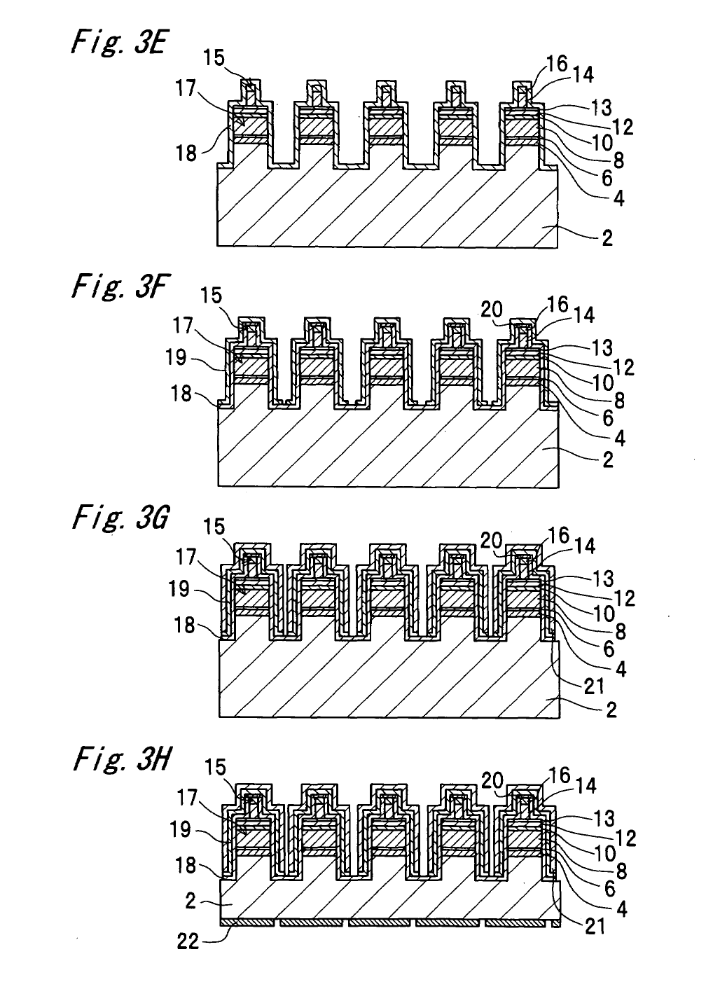

Subsequently, as shown in FIG. 3E, the SiO₂ film 18 is formed to a thickness of 0.2 μm on the surface of the p-type GaInP etching stop layer 13, the side surfaces and the upper surface of the ridge portion 15 and the entire inner surfaces of the grooves T. Due to the SiO₂ film 18 provided on the side surfaces of the ridge portion 15, light generated in the active layer by a current injected from the ridge portion 15 is confined in the sidewise direction by the refractive index difference within the active layer. Although the dielectric is formed of the SiO₂ film 18 in the present embodiment, it is acceptable to use another material of, for example, SiN (silicon nitride). Moreover, the material and the thickness of the dielectric can arbitrarily be selected in consideration of the refractive index and heat radiation. Moreover, the dielectric needs to be formed to a uniform thickness inside the grooves T. In the present embodiment, the SiO₂ film 18 is deposited by means of P-CVD.

Next, the SiO₂ film on the upper surfaces of the ridge portions 15 are removed by means of photolithography and etching, an AuZn film is deposited on the exposed upper surfaces of the ridge portions 15, and heat treatment is carried out at a temperature of about 400° C. As a result, an ohmic electrode 20 that is ohmically connected to the p-type GaAs cap layer 16 is formed.

Subsequently, 0.15-μm thick Ti and 0.2-μm thick Au are successively deposited on the SiO₂ film 18 by the sputtering method. Thereafter, by etching, the Ti and Au at the center in the widthwise direction of the bottom surface of each groove T is removed. The region from which the Ti and Au are removed is located between borderlines defined in positions 2.5 μm apart from the edges, which are the edges of both sides in the widthwise direction of the bottom surface of the groove T and also both sides continued to the side surfaces of the narrow width portion 17, toward the center in the widthwise direction of the bottom surface of the groove T. The center portion in the widthwise direction of the Ti and Au is thus removed, and a Ti/Au layer 19 as shown in FIG. 3F is formed. A high adhesion to the SiO₂ film 18 is obtained by virtue of Ti. It is acceptable to use Mo (molybdenum) in place of Ti, and it is acceptable to use Pt (platinum) in place of Au.

Subsequently, as shown in FIG. 3G, a Au-plated layer 21 is formed to a thickness of 3 μm on the Ti/Au layer 19. The Au-plated layer 21 is not formed in the center portion in the widthwise direction of the bottom surface of each groove T as in the Ti/Au layer 19. That is, on the Ti/Au layer 19 and the SiO₂ film 18 exposed at the center of the bottom surface of the groove T the Au plating is provided, and thereafter, the Au plating at the center portion in the widthwise direction of the bottom of the groove T is removed by etching. The region to be removed is located between borderlines defined in positions 2.5 μm apart from the edges, which are the edges of both sides in the widthwise direction of the bottom surface of the groove T and also both sides continued from the side surfaces of the narrow width portion 17, toward the center in the widthwise direction of the bottom surface of the groove T as in the Ti/Au layer 19. Moreover, the Au-plated layer 21 is not formed in a region 10 μm apart from the emission end surface and the end surface that opposes to the emission end surface toward the inside in the direction of the resonator length. With this arrangement, the troubles of dimensional inaccuracy caused by the existence of a metal film on indexing lines and the parting lines when the bar is formed by indexing the wafer and then dividing the wafer can be prevented.

It is acceptable to constitute the semiconductor laser device without forming the Au-plated layer 21 and provide an Au electrode as a surface electrode at the time of die bonding of the semiconductor laser device. However, the heat radiation characteristic of the semiconductor laser device and the stress distortion alleviation characteristic at the time of die bonding can be more advantageously improved by forming the Au-plated layer 21 having a comparatively large thickness at the time of wafer processing. Particularly, by forming the Au-plated layer 21 to a thickness of not smaller than 1 μm, the heat radiation performance can be effectively improved, and the stress when the brazing material adheres at the time of die bonding can be effectively alleviated.

Next, the back surface portion of the GaAs substrate 2 is removed by cutting by the back grinding method or etching, so that a thickness from the back surface of the GaAs substrate 2 to the surface of the p-side electrode layer 23 becomes 60 μm. Since the chip width of the semiconductor laser device of the present embodiment is 40 μm, there is no problem because a stable shape can be achieved during the manufacturing processes and in the state of the finished product of the semiconductor laser device even if the thickness is made 60 μm, which is smaller than the conventional thickness of 100 μm. The troubles of the occurrence of cracking and so on easily occur when the thickness is excessively small in the state of the wafer during the manufacturing processes, it is necessary to set an optimal thickness on the basis of the conditions of the manufacturing apparatus and the manufacturing processes.

Subsequently, an ohmic connection is formed by depositing AuGe (gold germanium) and Ni (nickel) by the sputtering method on the back surface of the n-type GaAs substrate and carrying out heat treatment, and Mo and Au are further deposited by the sputtering method. Then, as shown in FIG. 3H, the AuGe, Ni, Mo and Au films are removed by etching along the regions separated by a prescribed distance from the indexing lines and the parting lines, and an n-side electrode 22 is formed so that dimensional inaccuracy does not occur during the bar indexing and the chip dividing.

Subsequently, the wafer, on which the layers have been formed, is divided into bars from the p-type side, and the emission end surface and the end surface that opposes to the emission end surface are formed in the portion where the active layer is formed into a mixed crystal. By virtue of the active layer formed into a mixed crystal in the neighborhoods of the emission end surface (hereinafter referred to as a front end surface) and the end surface (hereinafter referred to as a rear end surface) that opposes to the emission end surface, the so-called window portion is formed. An asymmetrical coating film is formed on the front end surface and the rear end surface. In detail, an Al₂O₃ (alumina) film is formed on the front end surface, and a multilayer of Al₂O₃ (alumina) and Si (silicon) is formed on the rear end surface. It is acceptable to form a multilayer of Ta₂O₅ (tantalum oxide) and SiO₂, a multilayer of TiO₂ (titanium oxide) and Al₂O₃ or the like on the rear end surface. With this arrangement, the reflectance of the front end surface becomes 5%, and the reflectance of the rear end surface becomes 95%.

When the wafer is indexed into bars, the Ti/Au layer 19 of the electrode layer on the p-side exists in the neighborhood of the indexing lines. It is preferred that the Au-plated layer exists on the Ti/Au layer 19 taking the heat radiation of the emission end surface into consideration. However, the troubles of the obstruction of laser light emission or the like possibly occur as a consequence of the occurrence of the sagging of the soft Au-plated layer on the end surface or the like at the time of indexing. Therefore, it is preferred that the Au-plated layer is not provided in the neighborhood of the emission end surface. With regard to the heat radiation of the emission end surface, the heat radiation can be improved by making the brazing material tightly fit to the surface of the Ti/Au layer 19 in the neighborhood of the emission end surface at the time of die bonding described later.

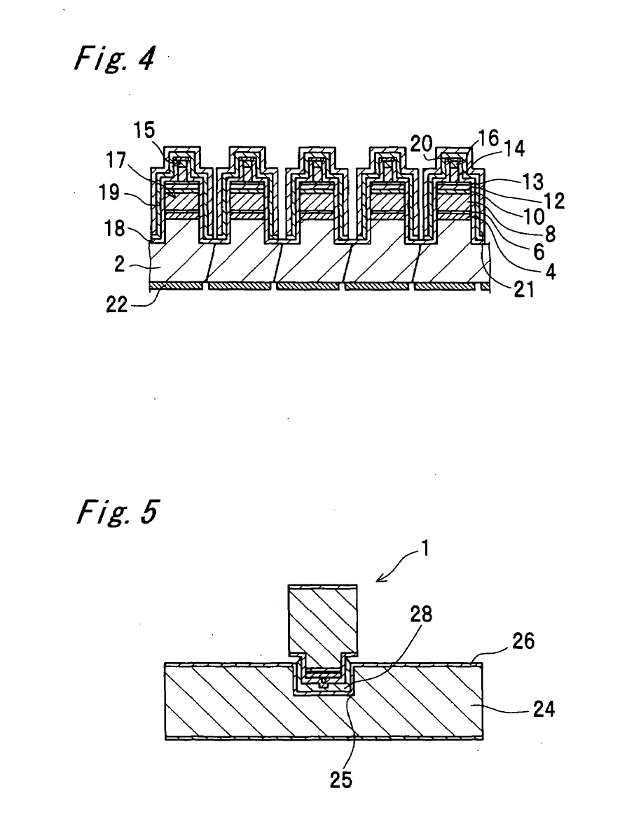

Subsequently, the wafer in the form of bars is divided into chips. In detail, scribe lines are drawn by a diamond cutter at the center in the widthwise direction of the bottom surface of the groove T and also at the center in the widthwise direction of the region where the p-side electrode layers 23 are mutually separated and the SiO₂ film is exposed. Then, by thrusting up the substrate 2 from the n-side electrode 22 side via the sheet, the substrate 2 is divided along the scribe lines and divided into chips. Since the GaAs substrate 2 that is generally 5 to 15 degrees off is used in the case of the red semiconductor laser, a dividing plane inclined by 5 to 15 degrees relative to the plane of the substrate 2 is formed as shown in FIG. 4. The upthrust positions of the chips on the n-side electrode 22 side needs to be determined in consideration of the inclination of the dividing plane. It is acceptable to draw scribe lines on the n-side electrode 22 side of the substrate 2 and thrust up the substrate 2 from the p-side electrode layer 23 side. Moreover, the portions to be thrust up for dividing or the portions where the scribe lines are drawn are respectively located at the surface of the SiO₂ film 18 on the p-side electrode 23 side and at the back surface of the substrate 2 on the n-side electrode 22 side. As described above, by carrying out the dividing in the portions where the electrodes 22 and 23 and, in particular, the hard electrode materials of Mo, Ti and the like do not exist, a satisfactory dividing plane free from the sagging and irregularity of the metallic material can be obtained.

In the semiconductor laser device 1 manufactured through the manufacturing processes, the width of the lower portion of the GaAs substrate 2, or the maximum width is much smaller than the width of the conventional semiconductor laser device. Concretely, in contrast to the fact that the width of the conventional semiconductor laser device has been 200 to 300 μm, the maximum width of the semiconductor laser device 1 of the present embodiment is 40 μm. With this arrangement, the semiconductor laser devices 1 of the present embodiment can be increased more largely than in the conventional case in terms of the manufacturable number thereof from a wafer of the same dimensions as those of the conventional one, and cost reduction of the semiconductor laser device 1 can consequently be achieved. Furthermore, the semiconductor laser device 1 of the present embodiment is able to effectively discharge the heat generated in the active layer 10 to the outside by virtue of the provision of the dielectric film 18 and the electrode layer 23 on the side surfaces of the active layer 10, and the width of the active layer 10 can therefore be reduced more largely than in the conventional case.

FIG. 5 is a view showing the appearance of the semiconductor laser device 1 of the embodiment mounted on a submount. As shown in FIG. 5, the submount 24 has a recess 25 in which the semiconductor laser device 1 is inserted. The recess 25 has a depth of 18 μm and a width of 35 μm. The width of the recess 25 is a width parallel to the width of the emission end surface of the semiconductor laser device 1 inserted in the recess 25. The lengthwise dimension of the submount 24 is 1610 μm, which is 10 μm shorter than the length of 1620 μm of the resonator length of the semiconductor laser device 1 inserted in the recess 25. The submount 24 is formed of AlN (aluminum nitride) having a good thermal conductivity. A Ti/Pt/Au film is formed on a surface on which the recess 25 of the submount 24 is formed and on a flat back surface (lower surface in FIG. 5). The Ti/Pt/Au film on the upper surface side of the submount is the p-side electrode 26 of the submount, and the p-side electrode 26 extends on the inner surface of the recess 25. A brazing material 28 formed of Au (70 wt %) and Sn (30 wt %) is uniformly deposited to a thickness of 3 μm on the inner surface of the recess 25 of the submount. By inserting a portion where the p-side electrode layer 23 of the semiconductor laser device 1 is formed into the recess 25 and melting the AuSn brazing material 28 in the recess 25 by heating, the melted AuSn brazing material 28 is put in contact with the p-side electrode layer 23 of the semiconductor laser device 1 without a gap.

The semiconductor laser device 1 is mounted on the submount 24 as follows. That is, the submount 24 is fixed to a stage, and the semiconductor laser device 1 is retained by a collet. Subsequently, the brazing material 28 in the recess 25 is melted by heating the submount 24 to a prescribed temperature. Then, by controlling the position of the collet, a portion covered with the p-side electrode layer 23 of the semiconductor laser device 1 is inserted into the recess 25 in which the melted brazing material 28 exists. In this case, the amount of insertion of the semiconductor laser device 1 into the recess 25 is controlled so that the melted brazing material 28 does not come in contact with the surface of the semiconductor laser device 1 not covered with the SiO₂ film 18. With this arrangement, a leakage current can be prevented from occurring as the result that the brazing material comes in contact with the GaAs substrate or the like. Moreover, the amount of insertion of the semiconductor laser device 1 into the recess 25 is controlled so that no excessive stress is generated in the semiconductor laser device 1. As a result, the occurrence of a stress distortion or the like attributed to the die bonding in the state in which the excessive stress is applied can be prevented.

In the semiconductor laser device 1 mounted on the submount 24, the front end surface and the rear end surface protrude from the end surfaces of the submount 24 each by 5 μm. In this case, the heating temperature and the heating time of the AuSn brazing material 28 are controlled so that the melted AuSn brazing material covers the surface of the p-side electrode 23 of the semiconductor laser device 1 in the mounting process. That is, the melted AuSn brazing material 28 sufficiently wets the surface of the p-side electrode 23 of the semiconductor laser device 1 from the ends of the recess 25 of the submount 24 to both the edge on the front end surface side and rear end surface side of the p-side electrode 23 and reacts with the surface portion of the p-side electrode 23. With this arrangement, the AuSn brazing material 28 is brazed to the surface of the p-side electrode 23 from the front end surface over to the rear end surface of the semiconductor laser device 1, so that a heat radiation path from the semiconductor laser device 1 to the submount 2 is formed via the AuSn brazing material 28. As a result, heat caused by the laser oscillation of the semiconductor laser device 1 can be conducted from the side surfaces of the active layer 10 to the submount 24 via the SiO₂ film 18, the p-side electrode 23 and the AuSn brazing material 28, and a sufficient heat radiation performance can be obtained. In particular, heat in the neighborhood of the emission end surface (front end surface) of which the heat value is greater than in the other portions can effectively be discharged to the submount 24.

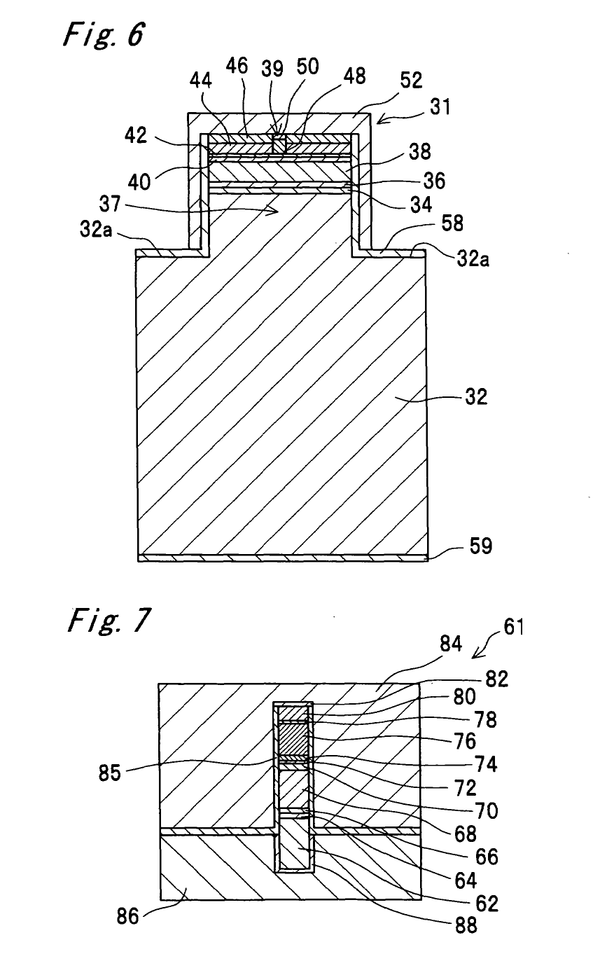

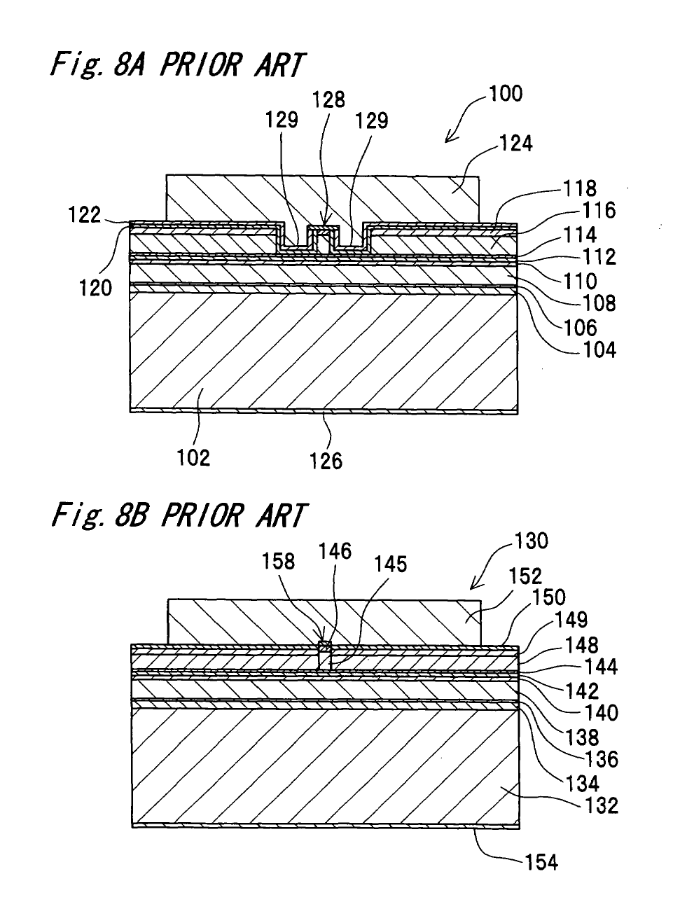

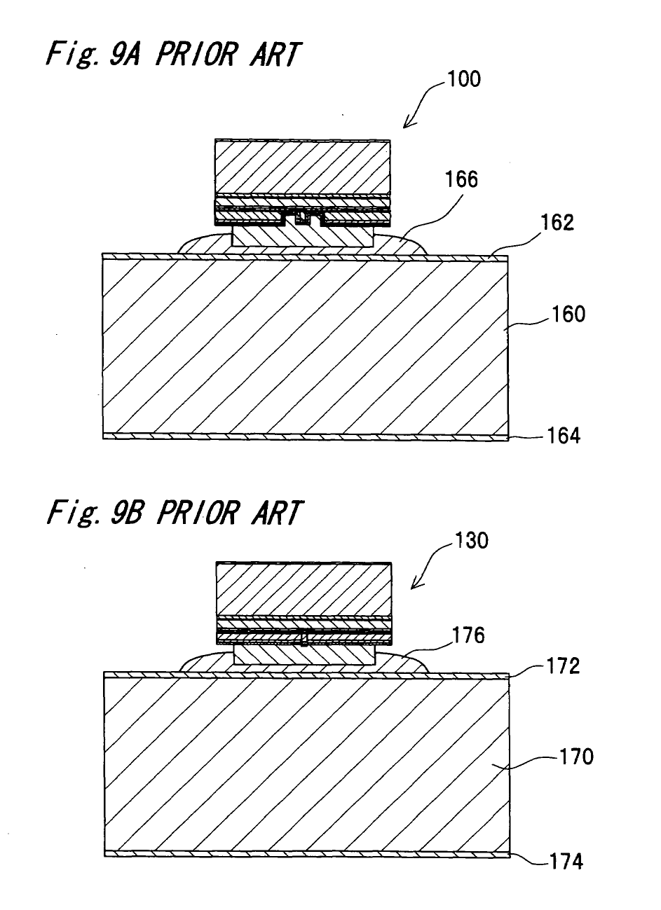

FIG. 6 is a sectional view showing the semiconductor laser device of the second embodiment of the present invention. In the semiconductor laser device 31, optical confinement of the laser light in the sidewise direction in the ridge portion is carried out not by the dielectric 18 as in the semiconductor laser device 1 of FIG. 1 but by a buried layer. In the semiconductor laser device 31, an n-type GaAs buffer layer 34, an n-type GaInP intermediate layer 36, an n-type AlGaInP cladding layer 38 as a lower cladding layer, a non-doped MQW active layer 40, a p-type AlGaInP cladding layer 42 as a first upper cladding layer, a p-type AlGaInP cladding layer 48 as a second upper cladding layer, and a p-type GaAs cap layer 50 are formed on a GaAs substrate 32. The p-type AlGaInP cladding layer 48 and the p-type GaAs cap layer 50 are formed in a ridge portion 39. The layers from the GaAs substrate 32 to the p-type GaAs cap layer 50 are formed as in the semiconductor laser device 1 of FIG. 1. An n-AlInP block layer 44 and an n-GaAs block layer 46 are formed by regrowth on an etching stop layer (not shown) formed on the surface of the p-type AlGaInP cladding layer 42 on both sides of the ridge portion. Also in the semiconductor laser device 31 of the present embodiment, a narrow width portion 37 having a width of 20 μm is formed as in the semiconductor laser device 1 of FIG. 1. The narrow width portion 37 is formed extending from an upper portion of the GaAs substrate 32 to the n-GaAs block layer 46 and the p-type GaAs cap layer 50, and a step portion 32a having a difference in width with respect to a lower portion of the GaAs substrate 32 is formed on both sides of the upper portion of the GaAs substrate 32. A distance in the thickness direction between the step portion 32a and the upper end of the narrow width portion 37 is 14 μm. An SiO₂ film 58 as a dielectric is formed on the side surfaces of the narrow width portion 37 and the surface of the step portion 32a, and a p-side electrode layer 52 is formed on the surfaces of the SiO₂ film 58 formed on the side surfaces of the narrow width portion 37, and on the upper surface of the narrow width portion 37. The p-side electrode layer 52 is also constructed of a Ti/Au layer put in contact with the SiO₂ film 58, an Au-plated layer formed on the surface of the Ti/Au layer, and an ohmic electrode formed of AuZn on the surface of the p-type GaAs cap layer 50 as in the p-side electrode layer 23 of the semiconductor laser device 1 of FIG. 1. An N-side electrode 59 is formed on the lower surface of the GaAs substrate.

The semiconductor laser device 31 of the present embodiment is also able to efficiently radiate heat to the submount on which the semiconductor laser device 31 is mounted via the SiO₂ film 58 and the p-side electrode layer 52 formed on the side surface of the active layer 40 as in the semiconductor laser device 1 of FIG. 1. As a result, with regard to the semiconductor laser device 31, the narrow width portion 37 including the active layer 40 is allowed to have a width of about 40 μm while securing the conventional oscillation characteristic and reliability, and the manufacturing cost can be reduced by achieving a more remarkable reduction in size than in the conventional case.

FIG. 7 is a sectional view showing the semiconductor laser device of the third embodiment of the present invention.

The semiconductor laser device 61 has a maximum width of 2.0 μm approximately equal to the width of the ridge portions 15 and 39 of FIGS. 1 and 6. In the semiconductor laser device 61, an n-type GaAs buffer layer 64, an n-type GaInP intermediate layer 66, an n-type AlGaInP cladding layer 68 as a lower cladding layer, a non-doped AlGaInP guide layer 70, a non-doped MQW active layer 72, a non-doped AlGaInP guide layer 74, a p-type AlGaInP cladding layer 76 as a first upper cladding layer, a p-type InGaP intermediate layer 78 and a p-type GaAs cap layer 80 are formed on an n-type GaAs substrate 62. An outer side surface of a lower portion of the n-type GaAs substrate 62 is connected to an n-side plated electrode 86 via an n-side ohmic electrode 88. The upper surface of the p-type GaAs cap layer 80 is connected to a p-side plated electrode 84 as an electrode layer via a p-side ohmic electrode 82. A dielectric 85 is provided as a cover on the side surfaces from the upper portion of the n-type GaAs substrate 62 to the p-type GaAs cap layer 80. The dielectric 85 extends on the surface of the n-side plated electrode 86, and the p-side plated electrode 84 extends on the side opposite to the n-side plated electrode 86 with respect to the dielectric 85. That is, the layers between the upper portion of the n-type GaAs substrate 62 and the p-type GaAs cap layer 80 are insulated from the p-side plated electrode 84 by the dielectric 85, and the p-side plated electrode 84 is insulated from the n-side plated electrode 86 by the dielectric 85.

In the semiconductor laser device 61 of the present embodiment, the laser light generated in the active layer 72 is confined in the sidewise direction by the dielectric 85 put in contact with both side surfaces of the active layer 72. By providing the p-side plated electrode 84 of a sufficient thickness on the surface of the dielectric 85, heat radiation to the submount on which the semiconductor laser device 61 is mounted is effectively achieved via a brazing material brazed to the p-side plated electrode 84. With this arrangement, a heat radiation characteristic sufficient for obtaining a stable oscillation characteristic is provided, and a more remarkable reduction in size than in the conventional case can be achieved by setting the width of the semiconductor laser device 61 to 2.0 μm. As a result, the manufacturing cost of the semiconductor laser device 61 can be remarkably reduced.

Although the red light-emitting semiconductor laser device using the AlGaInP based semiconductor has been illustrated in connection with each of the embodiments described above, it is acceptable to constitute a semiconductor laser device using another semiconductor material. Moreover, the output of the semiconductor laser device is not limited to the 200-mW class.

Moreover, the structure of the active layer is not limited to the MQW (multiple quantum well) structure.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor laser device comprising:
a substrate;
a lower cladding layer formed on the substrate;
an active layer formed on the lower cladding layer;
a first upper cladding layer formed on the active layer;
a dielectric that covers side surfaces of the first upper cladding layer, the active layer and the lower cladding layer; and
an electrode layer that covers the dielectric while being electrically connected to the first upper cladding layer.

2. The semiconductor laser device as claimed in claim 1, wherein
the electrode layer has a thickness of not smaller than 1 μm and not greater than 50 μm.

3. The semiconductor laser device as claimed in claim 1, wherein
a ridge portion including a second upper cladding layer and a cap layer is provided between the first upper cladding layer and the electrode layer.

4. The semiconductor laser device as claimed in claim 1, wherein
a narrow width portion having a width smaller than a width of a lower portion of the substrate includes the first upper cladding layer, the active layer and the lower cladding layer and the dielectric covers side surfaces of the narrow width portion.

5. The semiconductor laser device as claimed in claim 4, wherein
the narrow width portion includes an upper portion of the substrate.

6. The semiconductor laser device as claimed in claim 5, wherein
the dielectric covers a surface of a step portion continuous to the narrow width portion and covers the surface of the step portion between the upper portion and a lower portion of the substrate.

7. The semiconductor laser device as claimed in claim 6, wherein
the electrode layer covers at least part of a portion of the dielectric that covers the surface of the step portion.

8. A semiconductor laser device mounting structure comprising:
the semiconductor laser device claimed in claim 1; and
a submount having a recess on an inner surface of which an electrode is formed, wherein
the portion where the electrode layer of the semiconductor laser device is formed is inserted in the recess of the submount, and the electrode layer of the semiconductor laser device and the electrode of the submount are electrically connected together.

9. The semiconductor laser device mounting structure as claimed in claim 8, comprising:
a brazing material that is provided in the recess and brazes the electrode layer of the semiconductor laser device to the electrode of the submount.

10. The semiconductor laser device mounting structure as claimed in claim 8, wherein
a length of the submount in a direction parallel to a direction of a resonator length of the semiconductor laser device is shorter than the resonator length of the semiconductor laser device.

11. A semiconductor laser device manufacturing method comprising:
a step for forming a lower cladding layer on a wafer;
a step for forming an active layer on the lower cladding layer;
a step for forming a first upper cladding layer on the active layer;
a groove forming step for forming a groove that reaches at least the lower cladding layer;
a dielectric forming process for forming a dielectric on an inner surface of the groove;
a step for forming an electrode layer, which is electrically connected to the first upper cladding layer, on a surface of the dielectric; and
a step for dividing the wafer, on which the lower cladding layer, the active layer, the first upper cladding layer, the dielectric and the electrode layer are formed, along a bottom surface of the groove.

12. A semiconductor laser device mounting method comprising:
a step for arranging a brazing material in a recess of a submount wherein an electrode is formed on an inner surface of the recess;
a step for inserting a portion, in which the electrode layer of the semiconductor laser device claimed in claim 1 is formed, into the recess of the submount; and
a step for brazing the electrode layer of the semiconductor laser device to the electrode of the submount by heating the brazing material.
